(19) United States
(12) Patent Application Publication
(10) Pub. No.: US 2026/0206393 A1
(43) Pub. Date: Jul. 16, 2026

(54) ELECTRONIC DEVICE

(71) Applicant: Innolux Corporation, Miaoli County (TW)

(72) Inventors: Yu-Wen Chen, Miaoli County (TW); Yu-Wei Tu, Miaoli County (TW); Yung-Hsun Wu, Miaoli County (TW)

(73) Assignee: Innolux Corporation, Miaoli County (TW)

(21) Appl. No.: 19/425,992

(22) Filed: Dec. 18, 2025

Related U.S. Application Data
(60) Provisional application No. 63/745,792, filed on Jan. 16, 2025.

(30) Foreign Application Priority Data
Sep. 12, 2025 (CN) 202511306864.0

(51) Int. Cl. H10H 29/49; H10H 29/41; H10K 59/124; H10K 59/131

(52) U.S. Cl. CPC H10H 29/49; H10H 29/41; H10K 59/124; H10K 59/131

(57) ABSTRACT

An electronic device comprising a substrate, a first conductive layer, a first insulating layer, a second conductive layer and a conductive pattern is provided. The first conductive layer is disposed on the substrate, and comprises a first electrode and a second electrode. The first insulating layer is disposed on the first conductive layer. The second conductive layer is disposed on the first insulating layer, and comprises a third electrode and a fourth electrode, wherein in a normal direction of the substrate, the first electrode overlaps the third electrode to form a first capacitor, and the second electrode overlaps the fourth electrode to form a second capacitor. The conductive pattern overlaps a gap between the first capacitor and the second capacitor in the normal direction.

### CROSS-REFERENCE TO RELATED APPLICATION

This application claims the priority benefit of U.S. provisional application serial no. 63/745,792, filed on January 16, 2025, and China application serial no. 202511306864.0, filed on September 12, 2025. The entirety of each of the above-mentioned patent applications is hereby incorporated by reference herein and made a part of this specification.

### BACKGROUND

### Technical Field

The disclosure relates to an electronic device, and in particular to a display device.

### Description of Related Art

As the technology related to electronic device continues to advance, the electronic device is developing towards the higher resolution, the pixel density and/or the aperture ratio. However, in the limited layout space of the electronic device, adjacent conductive layers that transmit different signals will easily generate the parasitic capacitance or may cause the signal interference, thereby affecting the electrical performance of the electronic device.

### SUMMARY

The disclosure provides an electronic device that can have the improved electrical performance.

According to some embodiments of the disclosure, a transparent display device comprises a substrate, a first conductive layer, a first insulating layer, a second conductive layer and a conductive pattern. The substrate has a plurality of units, wherein at least one of the plurality of units comprises a transmissive region and a pixel region, and an area of the transmissive region is greater than an area of the pixel region. The first conductive layer is disposed on the substrate and comprises a first electrode and a second electrode correspondingly located in the pixel region. The first insulating layer is disposed on the first conductive layer. The second conductive layer is disposed on the first insulating layer and comprises a third electrode and a fourth electrode correspondingly located in the pixel region, wherein in a normal direction of the substrate, the first electrode overlaps the third electrode to form a first capacitor, and the second electrode overlaps the fourth electrode to form a second capacitor. The conductive pattern overlaps a gap between the first capacitor and the second capacitor in the normal direction.

According to some embodiments of the disclosure, an electronic device comprises a substrate, a first conductive layer, a first insulating layer, a second conductive layer and a conductive pattern. The first conductive layer is disposed on the substrate and comprises a first electrode and a second electrode. The first insulating layer is disposed on the first conductive layer. The second conductive layer is disposed on the first insulating layer and comprises a third electrode and a fourth electrode correspondingly located in the pixel region, wherein in a normal direction of the substrate, the first electrode overlaps the third electrode to form a first capacitor, and the second electrode overlaps the fourth electrode to form a second capacitor. The conductive pattern overlaps a gap between the first capacitor and the second capacitor in the normal direction, wherein there is a first distance between the first electrode and the second electrode in the first direction, there is a second distance between the third electrode and the fourth electrode in the first direction, and at least one of the first distance and the second distance is between 2 μm and 50 μm.

According to some embodiments of the disclosure, an electronic device comprises a substrate, a capacitor, a signal line and a conductive pattern. The capacitor is disposed on the substrate and comprises two electrodes, wherein the two electrodes overlap each other in a normal direction of the substrate. The signal line is disposed on the substrate, wherein the signal line and the capacitor are offset in the normal direction, and the two electrodes in the capacitor and the signal line are on different layers. The conductive pattern is disposed on the substrate, wherein at least part of the conductive pattern overlaps the signal line in the normal direction.

In order to make the above features and advantages of the disclosure more clearly understood, the embodiments are given below and described in detail with reference to the accompanying drawings.

### BRIEF DESCRIPTION OF THE DRAWINGS

FIG. 1 is a part of equivalent circuit of an electronic device according to one embodiment of the disclosure.

FIG. 2A is a partial top view of an electronic device according to one embodiment of the disclosure.

FIG. 2B is a partial top view of a pixel region in an electronic device according to one embodiment of the disclosure.

FIG. 2C is a partial cross-sectional view of a pixel region in an electronic device according to one embodiment of the disclosure.

FIG. 2D is a partial top view of the electronic device corresponding to the components in FIG. 2B.

FIG. 2E is a partial top view of the relationship between a conductive pattern and nodes of adjacent sub-pixel units in an electronic device according to one embodiment of the disclosure.

FIG. 3A is a partial top view of a pixel region in an electronic device according to another embodiment of the disclosure.

FIGS. 3B to 3D are each partial cross-sectional views of a pixel region in an electronic device according to another embodiment of the disclosure.

FIG. 4A is a partial top view of a pixel region in an electronic device according to another embodiment of the disclosure.

FIG. 4B is a partial cross-sectional view of a pixel region in an electronic device according to another embodiment of the disclosure.

### DESCRIPTION OF THE EMBODIMENTS

Reference will now be made in detail to exemplary embodiments of the disclosure, examples of which are illustrated in the accompanying drawings. Whenever possible, the same reference numerals are used in the drawings and the description to refer to the same or like parts.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include”, “comprise” and “have” are used in an open-ended fashion, and thus should be interpreted to mean “include, but not limited to… ”. Thus, when the terms “include”, “comprise” and/or “have” are used in the description of the present disclosure, the corresponding features, areas, steps, operations and/or components would be pointed to existence, but not limited to the existence of one or a plurality of the corresponding features, areas, steps, operations and/or components.

Directional terms such as “above” and “below” mentioned herein are used only with reference to the directions of the accompanying drawings. Therefore, the directional terms used are for illustrative purposes only and are not intended to limit the disclosure. In the accompanying drawings, each depicts the general characteristics of the methods, structures, and/or materials used in a particular embodiment. However, these drawings should not be interpreted as defining or limiting the scope or nature of the embodiments. For example, the relative sizes, thicknesses, and positions of various layers, regions, and/or structures may be reduced or exaggerated for clarity.

When the corresponding component (such as layer or area) is referred to “on another component (or the variant thereof)”, it may be directly on another component, or other component may exist between them. On the other hand, when the component is referred to “directly on another component (or the variant thereof)”, any component does not exist between them. Moreover, when a component is referred to “on another component (or the variant thereof)”, the component and the other component has a positional relationship in a top view direction, the component can be disposed above or below the other component, and the positional relationship is based on the orientation of the device.

It should be understood that, although the terms “first”, “second”, etc. can be used herein to describe various elements, layers and/or sections, these elements, layers and/or sections should not be limited by these terms. These terms are only used to distinguish one element layer or section from another element, layer or section. Thus, a first element, layer or section discussed below could be termed a second element, layer or section without departing from the teachings of the present disclosure. The first element and/or the second element in claims can refer to any element that meets the description in the specification without departing from the spirit and scope of the disclosure as defined by the appended claims.

It should be noted that the features in the following embodiments can be replaced, reorganized, or mixed to complete other embodiments without violating the spirit of the disclosure or causing any conflict.

“The electrical connection” described in the disclosure may refer to the direct connection or the indirect connection. In the case of the direct connection, the endpoints of two circuit components are directly connected or connected to each other through a conductor segment.

In the disclosure, the thickness, the length, and the width can be measured using an optical microscope, and the thickness can be measured using the cross-sectional images obtained using an electron microscope, but the disclosure is not limited thereto. Furthermore, any two values or directions used for comparison may have a certain degree of error. If a first direction is perpendicular to a second direction, the angle between the first and second directions may be between 80 and 100 degrees. If the first direction is parallel to the second direction, the angle between the first and second directions may be between 0 and 10 degrees.

The electronic device in the following embodiment may include a display device, an antenna device, a sensing device, a splicing device, a touch device, or a combination thereof, but the disclosure is not limited thereto. The electronic device may includes a rollable electronic device, a bendable electronic device, or a flexible electronic device. It should be noted that the electronic device may be any combination of the aforementioned, but the disclosure is not limited thereto.

The following examples illustrate exemplary embodiments of the disclosure, with the same reference numerals used in the drawings and description to represent the same or similar parts. The disclosure may be used in any electronic device with limited layout space. Taking a display device as an example, the electronic device may be a display device requiring high resolution, a display device requiring high aperture ratio, a transparent display device, or other suitable display devices.

In the disclosure, the pattern of the conductive layer obtained after performing patterning process may have the functions of signal transmission, serving as an electrode, shielding an electric field, shielding light, or a combination thereof, and may be referred as a conductive pattern, a pattern, and/or an electrode.

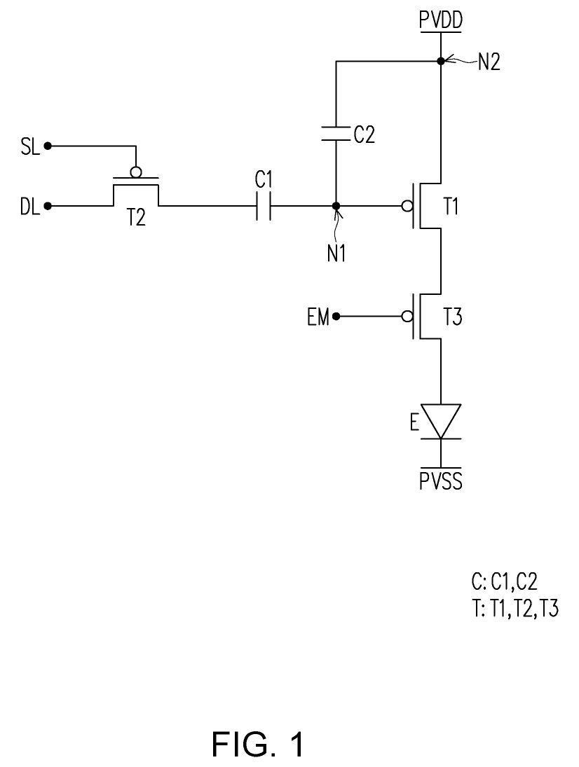

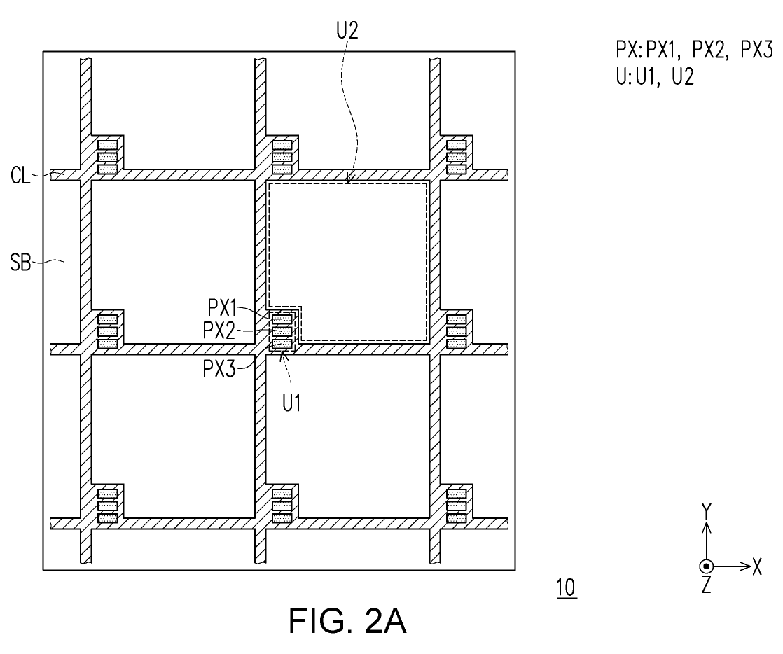

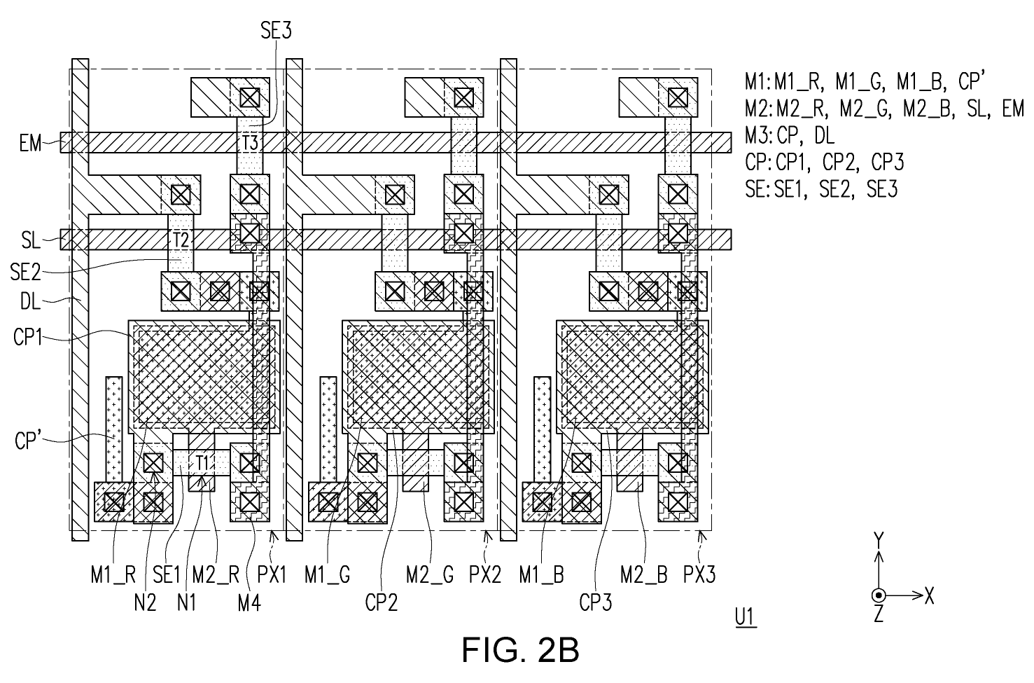

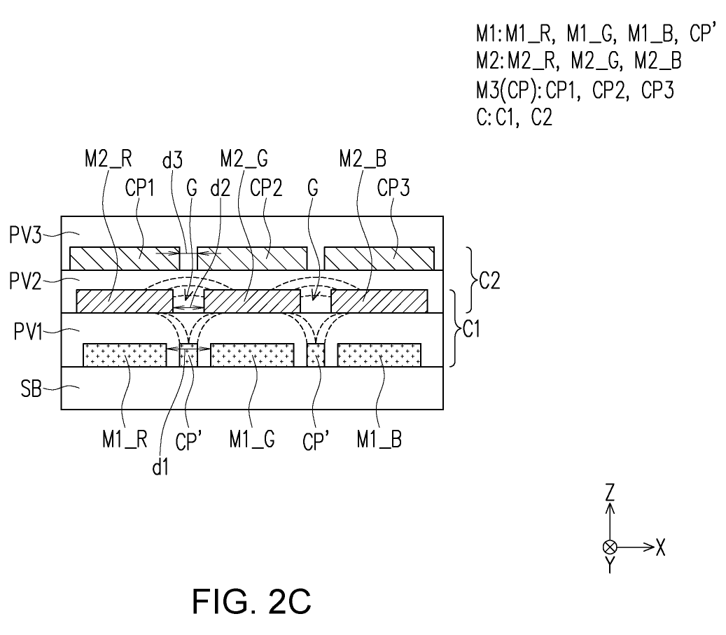

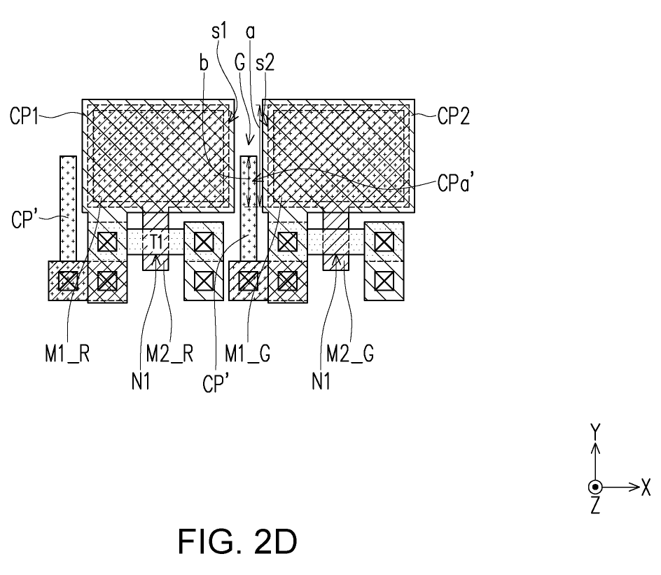

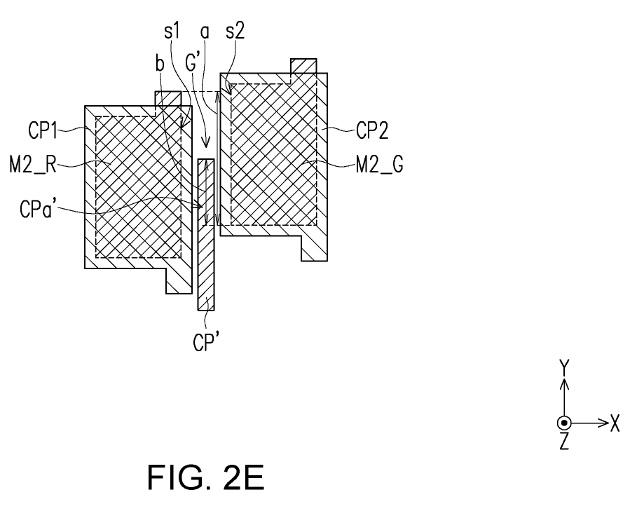

FIG. 1 is a part of equivalent circuit of an electronic device according to one embodiment of the disclosure, FIG. 2A is a partial top view of an electronic device according to one embodiment of the disclosure, FIG. 2B is a partial top view of a pixel region in an electronic device according to one embodiment of the disclosure, and FIG. 2C is a partial cross-sectional view of a pixel region in an electronic device according to one embodiment of the disclosure.

Referring to FIGS. 1 and 2A, an electronic device 10 includes a plurality of units U. One of the plurality of units U may be the minimum unit repeatedly disposed on a substrate SB. The electronic device 10 may be a display device having a light-emitting function, but the disclosure is not limited thereto.

Referring to the partial top view shown in FIG. 2A, in the present embodiment, the plurality of units U include a pixel region U1 and a transmissive region U2. The pixel region U1 is a region including a plurality of sub-pixels PX, and the transmissive region U2 is a region defined by a transmissive material and/or a transmissive element. In the present embodiment, an area of the transmissive region U2 is greater than an area of the pixel region U1. The plurality of units U may also include a signal line region in addition to the pixel region U1 and the transmissive region U2. Signal lines CL in the signal line region may be electrically connected to the plurality of sub-pixels PX in the pixel region U1. In some embodiments, both the pixel region U1 and the signal line region may include non-transmissive materials and/or non-transmissive elements. For example, the non-transmissive materials and/or the non-transmissive elements may include metal, light-emitting units, light-shielding materials, and/or other materials and/or elements that affect the light transmission.

Referring to the part of equivalent circuit diagram shown in FIG. 1, any of the plurality of sub-pixels PX in the pixel region U1 may include a light-emitting unit E, a plurality of transistors T (e.g., a driving transistor T1, a switching transistor T2, a light-emitting transistor T3, etc.), and at least one capacitor C (e.g., a capacitor C1 and a capacitor C2, etc.).

In some embodiments, the light-emitting element E may include a self-luminous material. In the present embodiment, the light-emitting element E may include a mini light-emitting diode (mini LED), an organic light-emitting diode (OLED), a micro light-emitting diode (micro LED), or a quantum dot light-emitting diode (QD LED), but the disclosure is not limited thereto.

For example, two ends of the light-emitting unit E are electrically connected to the light-emitting transistor T3 and a reference voltage PVSS, respectively. A control end of the driving transistor T1, the capacitor C1, and the capacitor C2 are electrically connected to a node N1. A first end of the driving transistor T1 and the capacitor C2 are electrically connected to a node N2 and a power voltage PVDD, and a second end of the driving transistor T1 is electrically connected to the light-emitting transistor T3. A control end of the switching transistor T2 is electrically connected to the scan line SL, and a first end and a second end of the switching transistor T2 are electrically connected to a data line DL and the capacitor C1, respectively. A control end of the light-emitting transistor T3 is electrically connected to an emission control line EM.

From another perspective, referring to the partial top view of the pixel region U1 shown in FIG. 2B and the partial cross-sectional view of the pixel region U1 shown in FIG. 2C, in the present embodiment, the electronic device 10 may include the following layers, but the disclosure is not limited thereto.

A material of the substrate SB may include a hard material, a soft material, or a combination thereof. For example, the material of the substrate SB may include glass, quartz, sapphire, polymethyl methacrylate (PMMA), polycarbonate (PC), polyimide (PI), polyethylene terephthalate (PET), or other suitable materials or a combination thereof.

In the present embodiment, the components disposed on the substrate SB may include a conductive layer M1, an insulating layer PV1, a conductive layer M2, an insulating layer PV2, a conductive layer M3, an insulating layer PV3, and a conductive layer M4 in this sequence in a direction Z. A material of the conductive layer M1, the conductive layer M2, the conductive layer M3 and the conductive layer M4 may be copper, titanium, silver, gold, aluminum, tin, magnesium, nickel, other suitable materials, or combinations thereof. A material of the insulating layer PV1, the insulating layer PV2 and the insulating layer PV3 may be inorganic materials (e.g., silicon oxide, silicon nitride, silicon oxynitride, etc.), organic materials, or stacked layers of at least two of the above materials. In some embodiments, the conductive layer M1, the conductive layer M2, the conductive layer M3, the conductive layer M4, the insulating layer PV1, the insulating layer PV2 and the insulating layer PV3 may be a single-layer structure or multi-layer structures. In some embodiments, an insulating layer may optionally be included between the conductive layer M1 and the substrate SB.

The conductive layer M1 may include an electrode M1_R located in a sub-pixel unit PX1, an electrode M1_G located in a sub-pixel unit PX2, and an electrode M1_B located in a sub-pixel unit PX3, wherein the electrode M1_R, the electrode M1_G, and the electrode M1_B may serve as bottom electrodes of the capacitor C1.

The conductive layer M2 may include an electrode M2_R located in the sub-pixel unit PX1, an electrode M2_G located in the sub-pixel unit PX2 and an electrode M2_B located in the sub-pixel unit PX3, wherein the electrode M2_R, the electrode M2_G and the electrode M2_B may serve as top electrodes of the capacitor C1. In some embodiments, the electrode M2_R, the electrode M2_G and the electrode M2_B may also serve as bottom electrodes of the capacitor C2.

The conductive layer M3 may include a pattern CP1 located in the sub-pixel unit PX1, a pattern CP2 located in the sub-pixel unit PX2, and a pattern CP3 located in the sub-pixel unit PX3, wherein the pattern CP1, the pattern CP2 and the pattern CP3 are separated from each other and may each serve as top electrodes of the capacitor C2.

In addition to serving as the electrodes, a plurality of the pattern CP1, the pattern CP2 and the pattern CP3 may also have the functions of signal transmission, electric field shielding, light shielding, or a combination thereof. For example, the plurality of the pattern CP1, the pattern CP2 and the pattern CP3 in the conductive layer M3 are electrically connected to a power voltage line that provides the power voltage PVDD and are used to provide a direct current (DC) signal of the power voltage PVDD, but the disclosure is not limited thereto.

In the disclosure, the conductive layer M1, the conductive layer M2, the conductive layer M3, and/or the conductive layer M4 may further include other patterns that are electrically connected to another conductive layer and transmit signals, but the disclosure is not limited thereto.

In some embodiments, the conductive layer M1, the conductive layer M2, the conductive layer M3 and/or the conductive layer M4 may also be used to form a gate, a source, or a drain of the plurality of transistors T. In addition, the conductive layer M1, the conductive layer M2, the conductive layer M3 and the conductive layer M4 may also be used to form the signal lines CL, such as scan lines, data lines, light control lines, power lines, etc. In the present embodiment, the conductive layer M2 may be used to form the gate of the transistor T, the scan line SL, and the emission control line EM, and the conductive layer M3 may be used to form the data line DL, but the disclosure is not limited thereto.

The semiconductor layer SE is disposed between the conductive layer M1 and the conductive layer M2, and can be used to form a semiconductor layer SE1, a semiconductor layer SE2, and a semiconductor layer SE3 of the driving transistor T1, the switching transistor T2, and the light-emitting transistor T3, respectively. In some embodiments, a material of the semiconductor layer SE includes single crystal silicon, low temperature polysilicon (LTPS), metal oxide semiconductor, or amorphous silicon, or a combination thereof, but the disclosure is not limited thereto.

In the present embodiment, the electronic device 10 further includes a plurality of conductive patterns CP’, wherein the plurality of conductive patterns CP’ overlap a gap G between the two adjacent capacitors C1 in the direction Z (a normal direction of the substrate SB). It is worth mentioning that the term “overlap” mentioned herein can mean “partially overlap” or “completely overlap” in the direction Z (the normal direction of the substrate SB).

For example, the plurality of conductive patterns CP’ are electrically connected to the power voltage line (not shown) that provides the power voltage PVDD and are used to provide the DC signal of the power voltage PVDD. Based on this, by providing the plurality of conductive patterns CP’, a parasitic capacitance generated between the nodes N1 of the adjacent sub-pixel units can be reduced. It is worth mentioning that the plurality of conductive patterns CP’ can also be electrically connected to other voltage lines (not shown) that provide the DC signal. For example, the DC signal can be a voltage line that provides the reference voltage PVSS, a reference voltage (VREF), or a reset voltage (VRST).

In the present embodiment, the plurality of conductive patterns CP’ are a part of the conductive layer M1, but the disclosure is not limited thereto. Specifically, at least one of the plurality of conductive patterns CP’ can be provided between any two adjacent electrodes in a direction X, and the plurality of conductive patterns CP’ and the two adjacent electrodes belong to the same layer.

FIG. 2D is a partial top view of the electronic device corresponding to the components in FIG. 2B.

In the disclosure, the two adjacent electrodes (or the patterns providing electrode functions) in the same conductive layer and the conductive pattern disposed between the two adjacent electrodes in a top view and providing the DC signal may have the following relationship. The conductive pattern may be in the same layer as the two electrodes or in a different layer, depending on the needs. For example, the two electrodes M2_R and M2_G of the conductive layer M2 and the conductive pattern CP’ of the conductive layer M1 in FIG. 2D are used as examples. A side s1 of the electrode M2_R adjacent to the electrode M2_G and a side s2 of the electrode M2_G adjacent to the electrode M2_R have overlapping portions in the direction X, and the overlapping portions have a length a in a direction Y. In the top view, the conductive pattern CP’ is disposed between the electrode M2_R and the electrode M2_G, and at least part of the conductive pattern CPa’ overlaps the side s1 of the electrode M2_R and the side s2 of the electrode M2_G in the direction X. The at least part of the conductive pattern CPa’ has a length b in the direction Y.

In the present embodiment, the length b and the length a satisfy the following relationship: b/a > 0.5.

In some embodiments, the conductive pattern CP’ can be replaced by other means for electrically connecting the same DC signal. For example, the conductive pattern CP’ can be replaced by the plurality of conductive patterns of different layers and at least one through-hole electrically connecting the plurality of conductive patterns of different layers, and satisfying the above relationship between the length a and the length b, thereby reducing the parasitic capacitance generated between the nodes N1 of the adjacent sub-pixel units.

In some embodiments, a distance between the two adjacent conductive patterns (or the two adjacent electrodes) in the same conductive layer is between 2 μm and 50 μm or between 2 μm and 5 μm. Taking the embodiment shown in FIG. 2C as an example, the distance between the two adjacent conductive patterns (or the two adjacent electrodes) in the same conductive layer can be a distance d1 between the electrode M1_R and the electrode M1_G of the conductive layer M1, a distance d2 between the electrode M2_R and the electrode M2_G of the conductive layer M2, and/or a distance d3 between the pattern CP1 and the pattern CP2 of the conductive layer M3.

FIG. 2E is a partial top view of the relationship between a conductive pattern and nodes of adjacent sub-pixel units in an electronic device according to one embodiment of the disclosure, and the description of the same technical contents in FIG. 2B is omitted.

Referring to FIG. 2E, in the present embodiment, the side s1 of the electrode M2_R adjacent to the electrode M2_G and the side s2 of the electrode M2_G adjacent to the electrode M2_R may have non-overlapping portions in the direction X. The definitions of the length a and the length b can refer to the embodiment shown in FIG. 2D, and will be omitted herein.

In the disclosure, the definitions and relationships of different electrode designs and the length a and the length b in FIG. 2D and FIG. 2E are applicable to all embodiments of the disclosure.

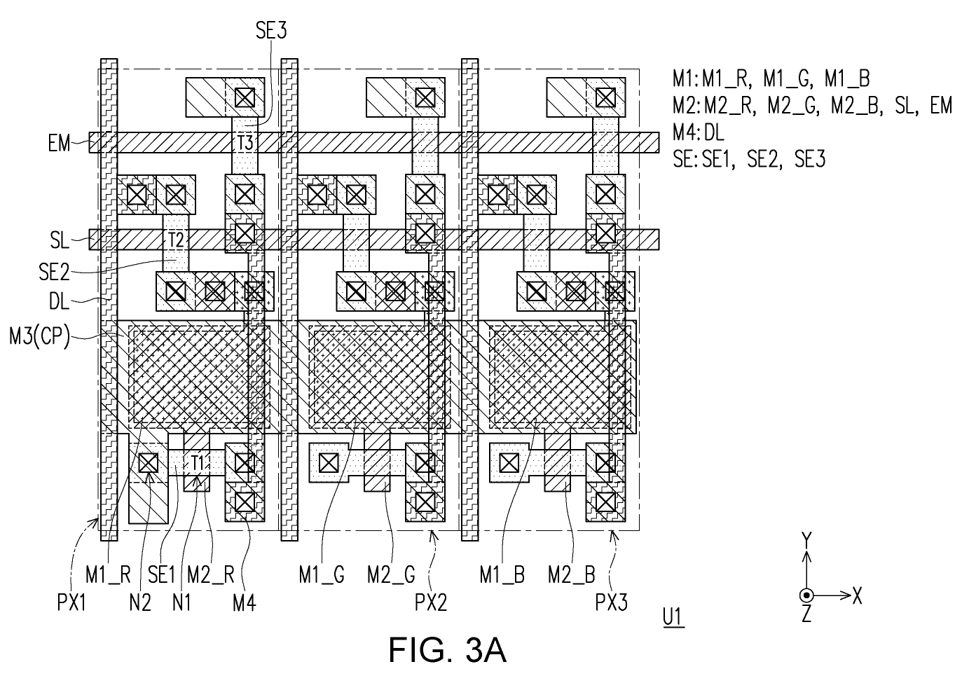

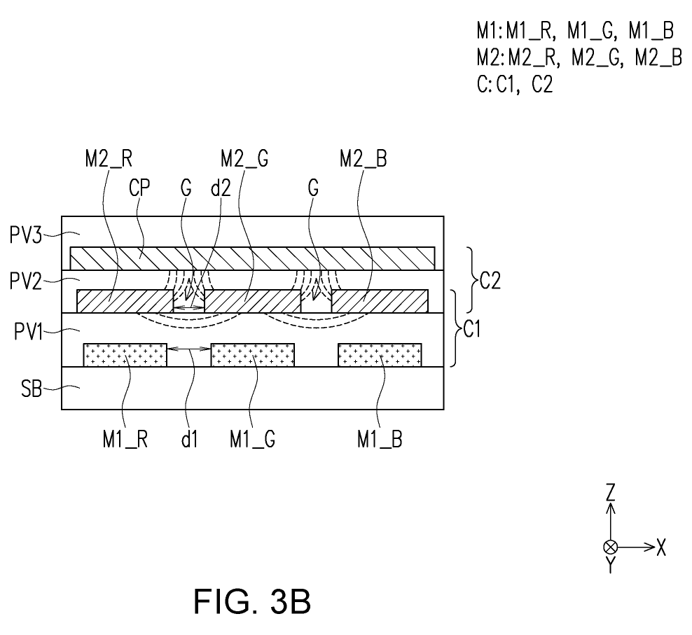

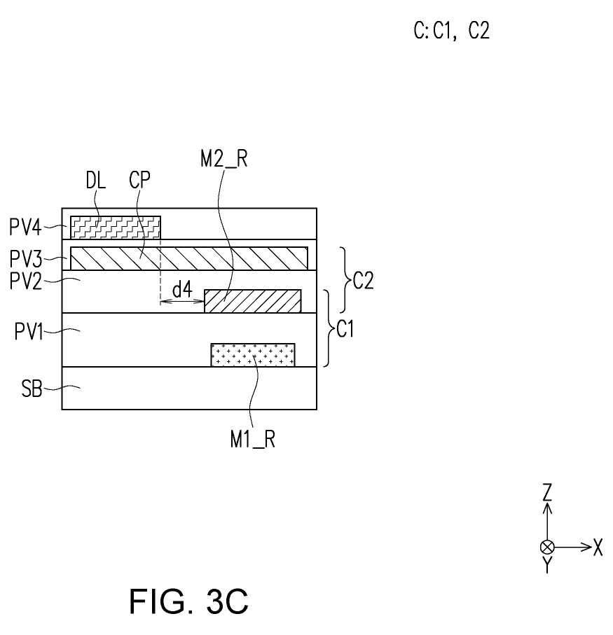

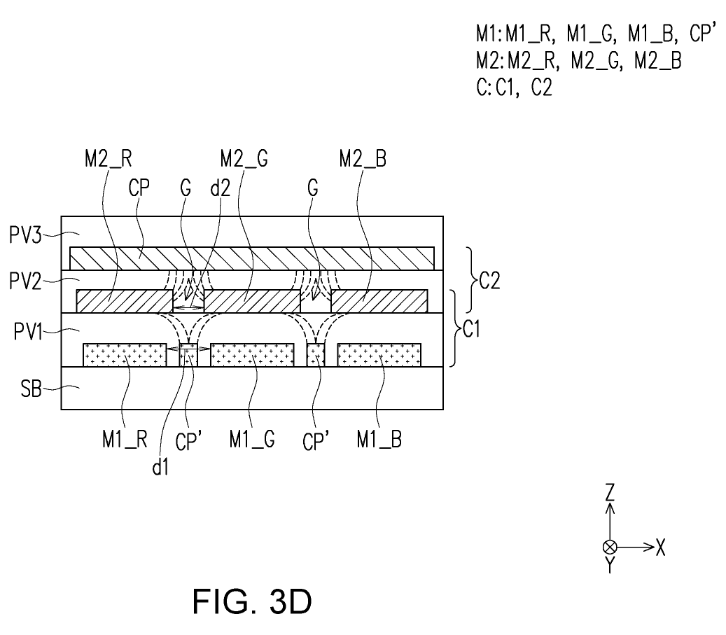

FIG. 3A is a partial top view of a pixel region in an electronic device according to another embodiment of the disclosure, and FIGS. 3B to 3D are each partial cross-sectional views of a pixel region in an electronic device according to another embodiment of the disclosure. It should be noted that the embodiment of FIGS. 3A-3D may use the component numbers and some contents of the embodiment of FIGS. 2A-2E, wherein the same or similar numbers are used to represent the same or similar components, and the description of the same technical contents is omitted.

Referring to FIGS. 3A-3C, the main difference between this embodiment and the embodiment shown in FIGS. 2A-2E is that the conductive layer M3 includes the conductive pattern CP, which overlaps the capacitors C1 of the plurality of sub-pixel units in the direction Z and overlaps the gaps G between the adjacent sub-pixel capacitors C1.

In detail, the conductive pattern CP of the conductive layer M3 can overlap with the capacitor C1 in the sub-pixel unit PX1, the sub-pixel unit PX2 and the sub-pixel unit PX3 located in the pixel region U1 and serve as the top electrode of the capacitor C2 in the corresponding sub-pixel unit PX1, the sub-pixel unit PX2 and the sub-pixel unit PX3. Furthermore, since the conductive pattern CP for providing the DC signal overlaps the gap G between the adjacent sub-pixel capacitors C1, the parasitic capacitance generated between the nodes N1 in the adjacent sub-pixel units can be reduced.

In the present embodiment, a conductive layer M4 can be used to form the data line DL. In some embodiments, the data line DL is offset from the capacitor C1, and the two electrodes forming the capacitor C1 and the data line DL are on different layers. Based on this, the data line DL can be separated from the capacitor C1 by the conductive pattern CP, thereby reducing the parasitic capacitance generated between the node N1 in the sub-pixel unit and the signal line transmitting the non-DC signal (e.g., the data line DL). This can reduce the possibility of the node N1 being affected by the parasitic capacitance or the possibility of the node N1 being affected by the signal line interference of the non-DC signal, resulting in a voltage deviation at the node N1.

In the present embodiment, at least one of the signal lines CL (e.g., the data line DL) and one of the electrodes (e.g., the electrode M2_R) of the capacitor (e.g., the capacitor C1 and/or the capacitor C2) are separated by a distance d4 in the direction X. The distance d4 is between 2 μm and 50 μm, or between 2 μm and 5 μm. In some embodiments, the conductive pattern CP further overlaps the capacitor C1 in the direction Z.

In some embodiments, to further reduce the influence of the parasitic capacitance and thereby improving the electrical performance of the electronic device 10, the embodiment in FIG. 3B can also be combined with the embodiment in FIG. 2C to form the plurality of conductive patterns CP’ located in the conductive layer M1 as an embodiment, as shown in FIG. 3D.

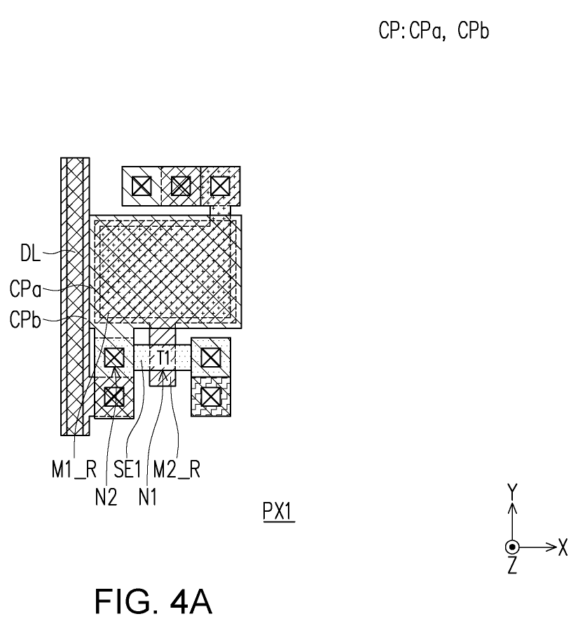

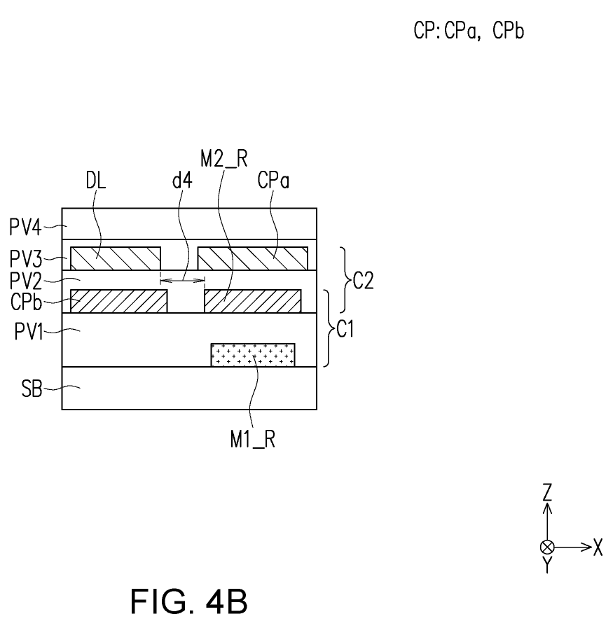

FIG. 4A is a partial top view of a pixel region in an electronic device according to another embodiment of the disclosure, and FIG. 4B is a partial cross-sectional view of a pixel region in an electronic device according to another embodiment of the disclosure. It should be noted that the embodiment of FIGS. 4A-4B may use the component numbers and some contents of the embodiment of FIGS. 2A-2E, wherein the same or similar numbers are used to represent the same or similar components, and the description of the same technical contents is omitted.

Referring to FIGS. 4A and 4B, the main difference between this embodiment and the embodiment shown in FIGS. 2A to 2E is that the sub-pixel unit located in the pixel region U1 includes the plurality of conductive patterns CP belonging to different layers.

In the present embodiment, taking the sub-pixel unit PX1 located in the pixel region U1 as an example, the plurality of conductive patterns CP include a conductive pattern CPa and a conductive pattern CPb, wherein the conductive pattern CPa belongs to a portion of the conductive layer M3, belongs to the same layer as the signal line CL (e.g., the data line DL), and overlaps the capacitor C1 in the direction Z, while the conductive pattern CPb belongs to a portion of the conductive layer M2, but the disclosure is not limited thereto.

Based on the above, since the plurality of conductive patterns CP belong to different layers are used to separate the data line DL and the capacitor C1, the parasitic capacitance generated between the node N1 in the sub-pixel unit and the signal line transmitting the non-DC signal (e.g., the data line DL) is reduced. This reduces the possibility of the node N1 being affected by the parasitic capacitance or the possibility of the node N1 being affected by the signal line interference of the non-DC signal, resulting in the voltage deviation at the node N1.

In summary, in some embodiments of the disclosure, since the at least one conductive pattern is disposed to overlap the gap between the two capacitors in the adjacent sub-pixel units, the parasitic capacitance generated between the nodes in the adjacent sub-pixel units is reduced, which reduced the possibility of the node being affected by the parasitic capacitance, thereby improving the electrical performance of the electronic device of the disclosure.

In other embodiments of the disclosure, the at least one conductive pattern is provided to separate the data line from the capacitor, which can be used to reduce the parasitic capacitance generated between the node in the sub-pixel unit and the signal line transmitting the non-DC signal. This can reduce the possibility of being affected by the parasitic capacitance or reduce the possibility of the node being interfered with by the signal line of the non-DC signal, resulting in the voltage deviation of the node, thereby improving the electrical performance of the electronic device of the disclosure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A transparent display device, comprising:
a substrate, having a plurality of units, wherein at least one of the plurality of units comprises a transmissive region and a pixel region, and an area of the transmissive region is greater than an area of the pixel region;
a first conductive layer, disposed on the substrate and comprising a first electrode and a second electrode correspondingly located in the pixel region;
a first insulating layer, disposed on the first conductive layer;
a second conductive layer, disposed on the first insulating layer and comprising a third electrode and a fourth electrode correspondingly located in the pixel region, wherein in a normal direction of the substrate, the first electrode overlaps the third electrode to form a first capacitor, and the second electrode overlaps the fourth electrode to form a second capacitor; and
a conductive pattern, overlapping a gap between the first capacitor and the second capacitor in the normal direction.

2. The transparent display device according to claim 1, wherein the conductive pattern is used to provide a direct current signal.

3. The transparent display device according to claim 1, further comprising:
a second insulating layer, disposed on the second conductive layer; and
a third conductive layer, disposed on the second insulating layer and comprising a first pattern and a second pattern,
wherein in the normal direction, the third electrode overlaps the first pattern to form a third capacitor, and the fourth electrode overlaps the second pattern to form a fourth capacitor.

4. The transparent display device according to claim 1, wherein the conductive pattern further overlaps the first capacitor and the second capacitor in the normal direction, the third electrode overlaps the conductive pattern to form a third capacitor, and the fourth electrode overlaps the conductive pattern to form a fourth capacitor.

5. The transparent display device according to claim 1, wherein a first side of the first electrode adjacent to the third electrode and a second side of the third electrode adjacent to the first electrode have overlapping portions in a first direction, and the overlapping portions have a first length in a second direction,
in a top view, the conductive pattern is located between the first side and the second side, at least part of the conductive pattern overlaps the first side and the second side in the first direction, and the at least part of the conductive pattern has a second length in the second direction,
wherein the first length and the second length satisfy following relationship:
0b/a > .5, where a is the first length, and b is the second length.

6. The transparent display device according to claim 1, wherein the conductive pattern, the first electrode, and the second electrode belong to the same layer.

7. An electronic device, comprising:
a substrate;
a first conductive layer, disposed on the substrate and comprising a first electrode and a second electrode;
a first insulating layer, disposed on the first conductive layer;
a second conductive layer, disposed on the first insulating layer and comprising a third electrode and a fourth electrode correspondingly located in the pixel region, wherein in a normal direction of the substrate, the first electrode overlaps the third electrode to form a first capacitor, and the second electrode overlaps the fourth electrode to form a second capacitor; and
a conductive pattern, overlapping a gap between the first capacitor and the second capacitor in the normal direction,
wherein there is a first distance between the first electrode and the second electrode in the first direction, there is a second distance between the third electrode and the fourth electrode in the first direction, and at least one of the first distance and the second distance is between 2 μm and 50 μm.

8. The electronic device according to claim 7, wherein the conductive pattern is used to provide a direct current signal.

9. The electronic device according to claim 7, further comprising:
a second insulating layer, disposed on the second conductive layer; and
a third conductive layer, disposed on the second insulating layer and comprising a first pattern and a second pattern,
wherein in the normal direction, the third electrode overlaps the first pattern to form a third capacitor, and the fourth electrode overlaps the second pattern to form a fourth capacitor.

10. The electronic device according to claim 9, wherein the first pattern and the second pattern are used to provide a direct current signal.

11. The electronic device according to claim 7, wherein the conductive pattern, the first electrode, and the second electrode belong to the same layer.

12. An electronic device, comprising:
a substrate;
a capacitor, disposed on the substrate and comprising two electrodes, wherein the two electrodes overlap each other in a normal direction of the substrate;
a signal line, disposed on the substrate, wherein the signal line and the capacitor are offset in the normal direction, and the two electrodes in the capacitor and the signal line are on different layers; and
a conductive pattern, disposed on the substrate, wherein at least part of the conductive pattern overlaps the signal line in the normal direction.

13. The electronic device according to claim 12, wherein the conductive pattern is used to provide a direct current signal.

14. The electronic device according to claim 12, wherein in the normal direction, the signal line and the capacitor have a spacing in a first direction perpendicular to the normal direction, and the conductive pattern further overlaps the capacitor and the spacing in the normal direction.

15. The electronic device according to claim 12, further comprising:
another conductive pattern, wherein the another conductive pattern overlaps the capacitor.

16. The electronic device according to claim 15, wherein the conductive pattern and the another conductive pattern are on different layers.

17. The electronic device according to claim 15, wherein the another conductive pattern and the signal line belong to the same layer.

18. The electronic device according to claim 12, wherein the conductive pattern and at least one of the two electrodes of the capacitor belong to the same layer.

19. The electronic device according to claim 12, wherein in the normal direction, a distance between the signal line and one of the two electrodes of the capacitor in a first direction perpendicular to the normal direction is between 2 μm and 50 μm.

20. The electronic device according to claim 18, wherein the distance is between 2 μm and 5 μm.
